(19) United States
(12) Patent Application Publication
(10) Pub. No.: US 2021/0319970 A1
(43) Pub. Date: Oct. 14, 2021

(54) ELECTRON BEAM APPLICATION DEVICE

(71) Applicant: Hitachi High-Tech Corporation, Minato-ku, Tokyo (JP)

(72) Inventors: Takashi Ohshima, Tokyo (JP); Hiroyuki Minemura, Tokyo (JP); Manabu Shiozawa, Tokyo (JP); Hideo Morishita, Tokyo (JP)

(21) Appl. No.: 17/053,417

(22) PCT Filed: May 21, 2018
(86) PCT No.: PCT/JP2018/019491

§ 371 Date: Nov. 6, 2020

(51) Int. Cl. H01J 1/34; H01J 37/26; H01J 37/073; H01J 37/153; H01J 37/10

(52) U.S. Cl. CPC H01J 1/34; H01J 37/261; H01J 37/073; H01J 2237/1534; H01J 37/10; H01J 2201/3423; H01J 37/153

(57) ABSTRACT

In a photoexcited electron source, a condenser lens optimally designed on an assumption that excitation light passes through a transparent substrate having a predetermined thickness and a predetermined refractive index cannot focus a focal point of the excitation light well on a photocathode film when the transparent substrate is different. Therefore, an optical spherical aberration correction plate 21 having a refractive index equal to a refractive index of a substrate of a photocathode at a wavelength of the excitation light is disposed between the photocathode 1 and the condenser lens 2. Alternatively, an optical spherical aberration corrector 20 configured to diverge or focus parallel light emitted to the condenser lens is provided. Accordingly, flares of the electron beam can be reduced and brightness of the photoexcited electron source can be increased.

### TECHNICAL FIELD

The present invention relates to an electron beam application device such as an electron microscope.

### BACKGROUND ART

In a high resolution electron microscope, a cold cathode electric field emission electron source or a schottky electron source has been used as a high brightness electron source in the related art. These electron sources have a needle shape with a small tip, and a virtual electron source size is several nm to tens of nm. In contrast, a photoexcited electron source using negative electron affinity is a planar electron source, and a focal point size of excitation light which is an electron source size is as large as about 1 pm. Since electrons emitted from the photoexcited electron source have good straightness, an increased brightness is expected by increasing a current density.

PTL 1 discloses a photoexcited electron source. An electron gun structure is shown in which a transparent substrate, specifically, a substrate obtained by attaching a photocathode film to a glass, is used as a photocathode, a small electron source is created by focusing excitation light on the photocathode film with a condenser lens placed close to the transparent substrate, and electron beams emitted in vacuum from this electron source are used. As a photocathode suitable for high brightness, in recent years, as shown in PTL 2, a semiconductor photocathode in which a photocathode layer is formed on a semiconductor substrate using a semiconductor crystal growth technique is under development. As shown in Non-Patent Literature 1, a semiconductor photocathode has performances similar to those of the schottky electron source.

### CITATION LIST

### Patent Literature

PTL 1: JP-A-2001-143648

PTL 2: JP-A-2009-266809

### Non-Patent Literature

Non-Patent Literature 1: Kuwahara and others, “Coherence of a spin-polarized electron beam emitted from a semiconductor photocathode in a transmission electron microscope” Applied Physics Letters, Vol. 105, p. 193101, 2014

### SUMMARY OF INVENTION

### Technical Problem

When the photoexcited electron source is used, it is necessary to focus a focal point of the excitation light on the photocathode film of the photocathode with the condenser lens. At this time, the excitation light passes through the transparent substrate of the photocathode and focuses the focal point on the photocathode film. In the photocathode in which the photocathode film is attached to the glass substrate, an electron gun can be implemented using the condenser lens optimally designed on an assumption that the excitation light passes through the glass substrate having a predetermined thickness and a predetermined refractive index. On the other hand, in recent years, a photocathode having a higher brightness is implemented by using the crystal growth technique in a semiconductor photocathode. In a case of a compound semiconductor single crystal substrate used in the semiconductor photocathode, such as GaP, the refractive index changes depending on a material thereof. Accordingly, the condenser lens optimally designed on the assumption that the excitation light passes through the transparent substrate having the predetermined thickness and the predetermined refractive index cannot focus the focal point of the excitation light well on the photocathode film when the transparent substrate is different.

For example, when it is assumed that a glass having a thickness of 1.2 mm and a refractive index n=1.5 is used as the transparent substrate of the photocathode, an inexpensive aspherical lens with good performance for a magneto-optical disk can be used as the condenser lens. However, when the transparent substrate is replaced with a different photocathode, this condenser lens cannot properly focus the focal point on the photocathode film. In addition, when the condenser lens is redesigned for each photocathode, the number of steps increases and accordingly, the cost also increases.

### Solution to Problem

An electron beam application device according to one embodiment of the invention includes a photocathode including a substrate and a photocathode film, a condenser lens configured to condense excitation light toward the photocathode, an extraction electrode which is disposed facing the photocathode and configured to accelerate an electron beam generated from the photocathode film of the photocathode by condensing the excitation light with the condenser lens and emitting the excitation light that passes through the substrate of the photocathode on the photocathode film, and an electron optical system in which the electron beam accelerated by the extraction electrode is guided. An optical spherical aberration correction plate having a refractive index equal to a refractive index of the substrate of the photocathode at a wavelength of the excitation light is disposed between the photocathode and the condenser lens.

Further, an electron beam application device includes a parallel light source, an optical spherical aberration corrector configured to diverge or focus a parallel light emitted from the parallel light source, a photocathode including a substrate and a photocathode film, a condenser lens configured to condense an excitation light toward the photocathode, the parallel light passing through the optical spherical aberration corrector being configured to be emitted as the excitation light, an extraction electrode which is disposed facing the photocathode and configured to accelerate an electron beam generated from the photocathode film of the photocathode by condensing the excitation light with the condenser lens and emitting the excitation light that passes through the substrate of the photocathode on the photocathode film, and an electron optical system in which the electron beam accelerated by the extraction electrode is guided.

Other technical problems and novel characteristics will be apparent from the description and the accompanying drawings of the specification.

### Advantageous Effect

By increasing brightness while reducing flares of an electron beam, high resolution of an electron beam application device such as an electron microscope can be achieved.

### BRIEF DESCRIPTION OF DRAWINGS

FIG. 1 is a schematic diagram of an electron beam application device including a photoexcited electron gun.

FIG. 2A is a diagram showing a light intensity distribution on a focal plane of a condenser lens in a transparent substrate.

FIG. 2B is a diagram showing a light intensity distribution on the focal plane of the condenser lens in the transparent substrate.

FIG. 3 is a diagram showing a relationship between a spherical aberration amount at a focal point of the condenser lens and a thickness of the transparent substrate.

FIG. 4A is a diagram showing an example of a configuration of an optical spherical aberration corrector.

FIG. 4B is a diagram showing a control mechanism of the optical spherical aberration corrector.

FIG. 5A is a schematic diagram of an electron gun provided with an activation chamber.

FIG. 5B is a diagram showing an example of a cathode pack.

FIG. 6 is a diagram showing an example of a photocathode.

FIG. 7 is a diagram showing an effect of the photocathode of FIG. 6.

### DESCRIPTION OF EMBODIMENTS

Hereinafter, an embodiment of the invention will be described with reference to the drawings.

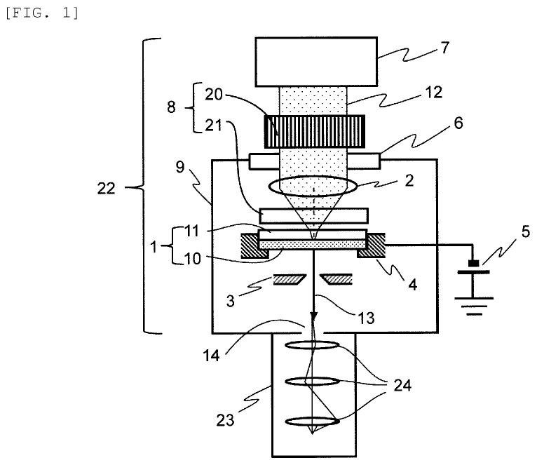

FIG. 1 is a schematic diagram of an electron beam application device including a photoexcited electron gun. When the electron beam application device is an electron microscope, a high brightness electron beam 13 generated from a photoexcited electron gun 22 is guided to a connected electron optical system housing 23 so that the electron beam application device acts as a microscope with components such as an electron lens 24.

In the electron gun 22, excitation light 12 generated from a parallel light source 7 placed outside a vacuum container 9 is introduced into the vacuum container 9 through a window 6, and the light is focused on a photocathode 1 with a condenser lens 2. The condenser lens is not particularly limited, and the cost can be reduced by using, for example, a lens for optical disc use. In this example, an aspherical lens having a focal distance f=4.2 mm and a numerical aperture (NA)=0.5, which is formed by a glass molding method for magneto-optical disk use, is used as the condenser lens 2. A refracting surface of this aspherical lens is optimized so that the excitation light can be focused to a limit of a wavelength when passing through a glass having a thickness of 1.2 mm and a refractive index n=1.5.

The photocathode 1 is mainly formed by a transparent substrate 11 and a photocathode film 10. The excitation light is emitted from a transparent substrate 11 side, and an electron beam is generated from a surface of the photocathode film 10. The electron beam 13 is accelerated by an electric field between the photocathode 1 and an extraction electrode 3 facing the photocathode 1, passes through an opening 14, and is emitted into the electron optical system housing 23. The photocathode 1 is housed in a cathode holder 4 and is electrically coupled to an acceleration power source 5 to define acceleration energy of the generated electron beam. The photocathode 1 uses a phenomenon known as an electron source using negative electron affinity. The photocathode film 10 is a p-type semiconductor and GaAs is typically used. Cs adsorption is performed on the surface of the photocathode film 10 for lowering a work function. The transparent substrate 11 is made of GaP (100) single crystal having a thickness of 0.4 to 0.5 mm in order to epitaxially grow a crystal of the photocathode film 10.

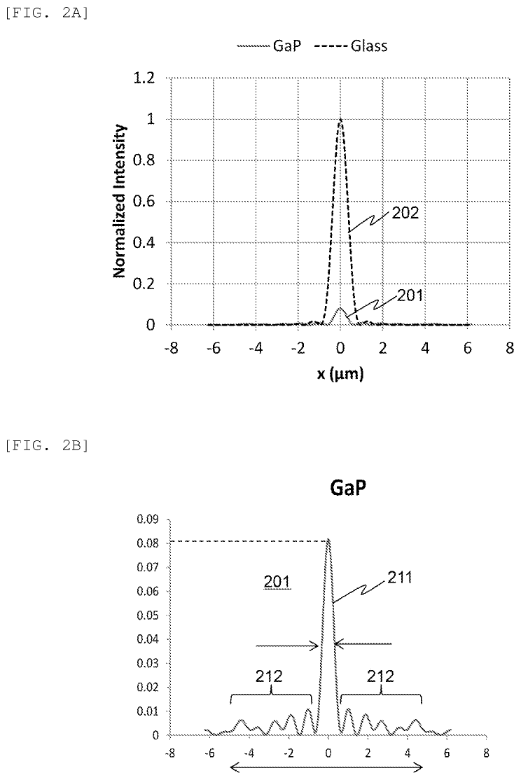

FIG. 2A shows a light intensity distribution when the light passes through the transparent substrate 11 and is focused on the photocathode film 10 with the condenser lens 2. A solid line 201 shows a light intensity distribution when the transparent substrate 11 is a GaP substrate having a thickness of 0.5 mm. As a comparative example, a broken line 202 shows a light intensity distribution when the transparent substrate 11 is a glass substrate having a thickness of 1.2 mm and a refractive index n=1.5. Here, a horizontal axis shows a shift from a focal point position (position where a light intensity is maximum), and a vertical axis shows a relative intensity of light, specifically, a relative intensity when a maximum light intensity on the glass substrate is 1. Since the condenser lens 2 is designed to have a minimum spot diameter when the light passes through the glass substrate having the thickness of 1.2 mm and the refractive index n=1.5, a performance of the condenser lens 2 as designed cannot be exhibited when the light passes through the GaP substrate having the thickness of 0.5 mm. FIG. 2B is an enlarged view of the solid line 201. A wavelength of light emitted to the GaP transparent substrate is 780 nm. The wavelength of light maybe selected from wavelengths having high transmittance for the GaP. At this time, a full width at half maximum of a central beam 211 is extremely narrow at about 0.6 μm, and it is recognized that flares 212 appear over a region centered on the central beam 211 and having a diameter of about 10 μm. As a result, the flares are also superposed on the electron beam 13 generated from the photocathode film 10. When the electron beam 13 scans a sample to forma two-dimensional image, blurring occurs in the two-dimensional image during high-resolution observation.

This is because the refractive index of GaP is n=3.2 and is greater than a refractive index of glass n=1.5, and a spherical aberration becomes large. As the flares caused by the spherical aberration increase on a focal plane of the excitation light, flares having a large diameter are superimposed on the generated electron beam.

Therefore, in the present embodiment, an optical spherical aberration correction unit 8 is provided in an optical path of the excitation light. Specifically, there are two types. At least one or both of an optical spherical aberration corrector 20 provided between the parallel light source 7 and the condenser lens 2 or an optical spherical aberration correction plate 21 provided between the condenser lens 2 and the photocathode 1 are used. When all spherical aberrations are corrected, as shown by the broken line 202 in FIG. 2A, the light intensity distribution having minimum flares is obtained and the flares of the electron beam 13 are also minimized. On the other hand, in a case of the broken line 202, a full width at half maximum of the central beam is 0.8 μm and is larger than that in a case of the solid line 201. Since the spherical aberration increases as the full width at half maximum of the central beam narrows, a spherical aberration amount may be adjusted and used when there is an optimum condition for observation between the solid line 201 and the broken line 202.

A specific configuration of the optical spherical aberration correction unit 8 will be described. The optical spherical aberration correction plate 21 is a plate having a refractive index equal to a refractive index of a substrate of a photocathode at a wavelength of the excitation light. Specifically, it is convenient to use a substrate made of the same material as the transparent substrate 11, and when the GaP substrate is used as the transparent substrate 11, it is preferable to use GaP also for the optical spherical aberration correction plate 21. FIG. 3 shows a relationship between a spherical aberration amount at a focal point of the condenser lens 2 and a thickness of a transparent substrate. In the case of glass (n=1.5), the spherical aberration amount is minimum at a thickness of 1.2 mm as shown by a broken line 302. On the other hand, in the case of the GaP substrate, as shown by a solid line 301, a large spherical aberration amount occurs at a thickness of 0.5 mm, whereas the spherical aberration amount is minimum at a thickness of about 1.7 mm. When the optical spherical aberration correction plate 21 made of GaP single crystal is used as the optical spherical aberration correction unit 8, a total thickness of the transparent substrate 11 and the optical spherical aberration correction plate 21 may be 1.7 mm for total correction. Therefore, when the thickness of the transparent substrate 11 of the photocathode 1 is 0.5 mm, a thickness of the optical spherical aberration correction plate 21 may be 1.2 mm. To obtain an intermediate correction amount instead of the total correction, the thickness of the optical spherical aberration correction plate 21 may be selected from thickness less than 1.2 mm.

Here, an example in which a GaP substrate is used as the transparent substrate 11 of the photocathode 1 has been described, but even a photocathode using another transparent substrate can be corrected according to the refractive index. For example, when a crystal such as AlAs, GaAlAs, ZnSe, GaN, and GaInN is used as the transparent substrate 11 of the photocathode 1, similarly, by using the optical spherical aberration correction plate 21 made of the same material and optimizing the thickness thereof for a desired correction amount, an appropriate correction amount can be selected and high-resolution observation can be achieved without changing the condenser lens.

Although it has been described that the photocathode 1 includes the photocathode film 10 and the transparent substrate 11, in a case of a semiconductor photocathode, an intermediate layer and a buffer layer may be formed between the two in order to obtain a desired crystal structure when a photocathode layer is formed on the transparent substrate. Similar effects can be obtained in such a photocathode 1 as well. This intermediate layer and the like need to be sufficiently thinner than the transparent substrate 11 to allow the excitation light to pass through since the excitation light is emitted from the transparent substrate 11 side.

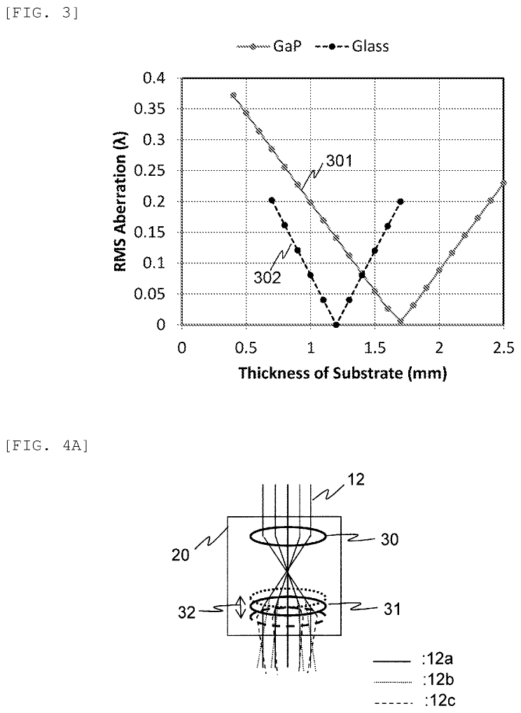

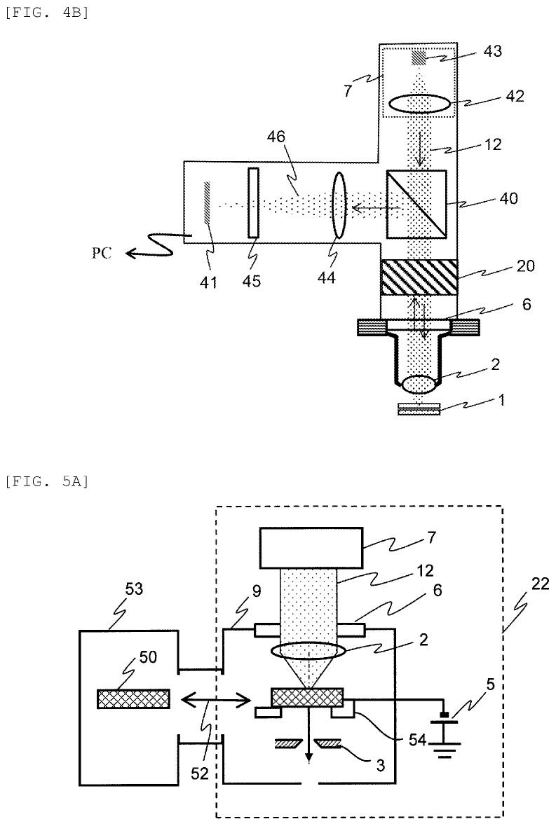

On the other hand, as shown in FIG. 4A, the optical spherical aberration corrector 20 includes a first convex lens 30 and a second convex lens 31 that face each other and to which the excitation light 12 is emitted, and a lens position adjusting mechanism 32 that finely moves the second convex lens 31 in an optical axis direction of the excitation light 12. When a distance between principal surfaces of the two convex lenses is the same as a sum of focal distances of the two, the emitted excitation light 12 passes as parallel light (solid line 12a). By adjusting this distance, the passing light becomes a divergent beam (dotted line 12b) or a convergent beam (dashed line 12c). Accordingly, the spherical aberration of the focal point of the condenser lens 2 can be corrected. The second convex lens 31 is finely moved in FIG. 4A, and the same effect can be obtained by finely moving the first convex lens 30 or finely moving both of them since the distance between the first convex lens 30 and the second convex lens 31 may be changed.

FIG. 4B shows a control mechanism of the optical spherical aberration corrector 20. Alight source 43 is a laser diode, and divergent light from the light source 43 is converted into the parallel excitation light 12 with a collimator lens 42. The parallel light source 7 in FIG. 1 has a configuration corresponding to the light source 43 and the collimator lens 42. The excitation light 12 passes through a beam splitter 40, enters a vacuum chamber of the electron gun through the window 6, and is focused on the photocathode 1 with the condenser lens 2. Reflected light 46 reflected from the photocathode film is converted into parallel light with the condenser lens 2, laterally bent by the beam splitter 40, and enlarged and projected on an imaging element 41 with an imaging lens 44. When an intensity of the reflected light 46 is too high for the imaging element 41, the intensity is appropriately attenuated by a neutral density (ND) filter 45 to measure a spatial distribution of the light intensity. Here, when a focal distance f of the condenser lens 2 is 4.2 mm and a lens having a focal distance f=1000 mm is used as the imaging lens 44, a 23.8-fold image on the photocathode film is projected on the imaging element 41. Accordingly, the flares superimposed on the focal point can be observed by monitoring this output with a PC or the like. By adjusting the optical spherical aberration corrector 20 provided between the beam splitter 40 and the condenser lens 2 while looking at an enlarged image of the focal point so that the flare image is optimal for the electron optical system, the electron beam can be optimized. A target focal point and a flare shape are determined as a condition for a best observation result by the electron beam.

The present embodiment describes an example in which both the first lens and the second lens are convex lenses and both have the same focal distance as an example of configuring the optical spherical aberration corrector 20, and the same effect can be obtained even when the optical spherical aberration corrector 20 is configured with lenses having different focal distances when a diameter of light needs to be changed. Further, one of the lenses may be a concave lens. In this case, since the optical spherical aberration corrector 20 does not have a condensing point and an interval between both lenses can be narrowed, there is an advantage that the optical spherical aberration corrector 20 can be made more compact. Further, the optical spherical aberration corrector 20 may be formed with a larger number of lenses, and the same effect can be obtained when they have a function of slightly diverging or condensing the parallel light.

As described above, the optical spherical aberration correction plate 21 is provided between the condenser lens 2 and the photocathode 1, and the optical spherical aberration corrector 20 may be adjusted with the mechanism shown in FIG. 4B. Further, although the example in which the optical spherical aberration corrector 20 is placed in atmosphere is shown, the same effect can be obtained by placing it in vacuum.

Further, the example in FIG. 4B discloses that the laser diode is used as the light source. When pulsed light or high intensity light is used or when the wavelength needs to be changed, optical components are disposed on an optical table and the like to form a light source optical system as the light source, and excitation light is introduced from the light source optical system with an optical fiber. In this case, a fixed optical fiber end corresponds to the light source 43.

Further, when the laser diode is used as the light source 43 and the excitation light 12 is polarized, transmittance of the excitation light 12 can be increased by using a polarization beam splitter as the beam splitter 40. At this time, a polarization plane of the reflected light 46 is rotated so as not to return to the light source 43 by providing a ¼ wavelength plate directly below the polarization beam splitter 40, so that light returned to the laser diode 43 can be minimized and an operation can be stabilized.

FIGS. 5A and 5B show an example of mounting the optical spherical aberration correction plate 21. An electron emission surface of the photocathode 1 is surface-sensitive, and its performance lowers due to an influence of residual gas. Therefore, as shown in FIG. 5A, an activation chamber 53 is provided adjacent to the electron gun 22. The activation chamber 53 is always equipped with a mechanism for surface cleaning, Cs vapor deposition, oxygen introduction, and the like (not shown) to reactivate a deteriorated surface of the photocathode film 10, and therefore the performance of the photocathode 1 can be maintained for a long time. At this time, the photocathode 1 moves back and forth between the electron gun 22 (vacuum container 9) and the activation chamber 53 with a transport mechanism 52. In order to facilitate this movement, the photocathode 1 is accommodated in a holder 51 as a cathode pack 50. FIG. 5B shows an example of a configuration of the cathode pack 50. By accommodating the photocathode 1 in the holder 51 so that the optical spherical aberration correction plate 21 is in contact with the substrate of the photocathode 1, loss due to reflection at the GaP substrate/vacuum interface can be effectively reduced. A cathode stage 54 is provided in the electron gun 22, and the cathode pack 50 is placed on the cathode stage 54 and used as an electron source. Further, there is an advantage that when a gate valve is provided between the activation chamber 53 and the electron gun 22 (vacuum container 9), the photocathode 1 and the optical spherical aberration correction plate 21 can be exchanged by opening the activation chamber 53 to the atmosphere while keeping the inside of the electron gun vacuum. Even in the present example, when the photocathode uses a transparent substrate made of another material, the cathode pack 50 can be formed together with the optical spherical aberration correction plate 21 made of the same material as the transparent substrate.

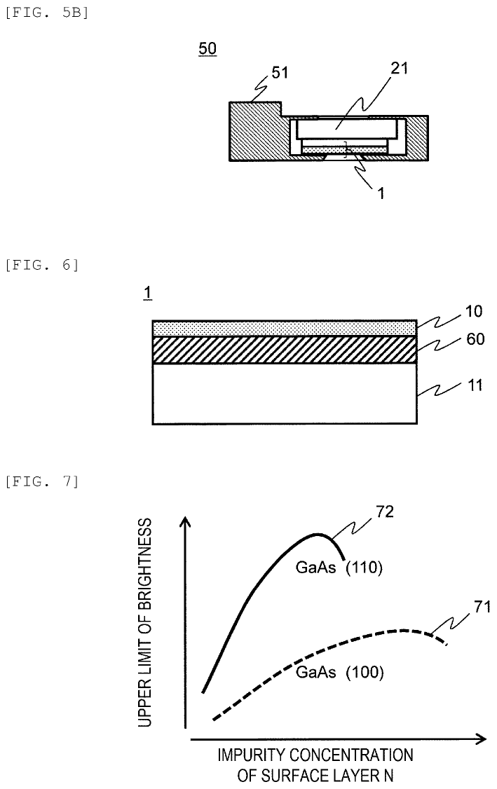

FIG. 6 shows the photocathode 1 that can be used in the electron beam application device of the present embodiment. In a semiconductor photocathode, crystal growth is normally performed so that a plane orientation of a surface of the photocathode film is a (100) plane because of ease of crystal growth. However, in the photocathode of FIG. 6, the plane orientation of the surface of the photocathode film is a (110) plane. Although the plane orientation depends on a crystal growth condition and the like, there is no problem even if the plane orientation is deviated within ±4 degrees. A GaP single crystal is used as the transparent substrate 11, and an AlGaAs buffer layer 60 is epitaxially grown on the transparent substrate 11 to a thickness of about 1 μm. A material of the buffer layer 60 is not limited thereto, and may be selected from materials which have a lattice constant matching so as not to give strain to GaAs which is the material of the photocathode film 10, have a wider band gap than GaAs, and are transparent to the excitation light. On the buffer layer 60, p-type GaAs is grown as the photocathode film 10. It is important that a thickness of the photocathode film 10 is sufficiently smaller than the spot diameter of the excitation light, and is equal to or less than 0.1 μm. As a feature of the photocathode 1 shown in FIG. 6, an upper limit of a current density is larger than that of a photocathode using the (100) plane in the related art, and as a result, higher brightness can be achieved.

An effect will be described with reference to FIG. 7. A horizontal axis of a graph is an impurity concentration of a photocathode film surface layer, and a vertical axis is an upper limit of brightness of the photocathode. A characteristic shown by the photocathode having the plane orientation of the GaAs photocathode film surface being the (100) plane is a characteristic 71 (dashed line), and a characteristic shown by the photocathode having the plane orientation of the GaAs photocathode film surface being the (110) plane is a characteristic 72 (solid line). In a case of the photocathode film 10 with crystal grown on the GaAs (100) surface, immediately after electrons are started to be emitted, electrons trapped in a surface level increase an electron potential on the surface, so that the current density immediately decreases, and the current density that can be constantly emitted from the photocathode film 10 is greatly limited. To prevent this, it is effective to increase the concentration of p-type impurities in the vicinity of the surface and recombine charges accumulated in the surface layer with holes in a valence band to remove them. Therefore, as shown by the characteristic 71 (dashed line), a maximum value of the brightness obtained by increasing the impurity concentration of the surface layer increases, but when the number of impurity atoms increases too much, the maximum value of the brightness decreases due to lattice defect and increasing inactive impurities. Therefore, there is an optimum impurity concentration for high brightness. In contrast, the surface level which is an obstacle to the high brightness can be reduced by selecting the plane orientation. Since the GaAs (110) plane has a small surface level in the band gap, the upper limit of the brightness can be made larger as shown by the characteristic 72 (solid line). The transparent substrate 11 is not limited to a GaP single crystal substrate as long as it is a single crystal transparent to the excitation light, and a single crystal substrate such as AlAs, GaAlAs, ZnSe, GaN, and GaInN can also be used.

By the way, one of reasons of the high brightness of the photocathode using GaAs as the material of the photocathode film 10 is that the electron beam emitted in vacuum is concentrated at a narrow angle (emission angle is narrow). Waves are refracted at an interface of regions having different effective masses due to changes in the wavelength. Accordingly, the electron emission angle is narrowed in the emission to vacuum from a region having a small effective mass. An effective mass of the conduction band of GaAs is 0.067 times the mass mo in vacuum. From the above relationship, the high brightness can be achieved by forming the photocathode film 10 with a material having an effective mass smaller than that of GaAs. As an example, it is effective to use a crystal (mixed crystal) in which InAs is mixed with GaAs, as Ga_{X}In_{(1-X)}As, the effective mass in the vicinity of X=0.7 is 0.05 m₀, and the effective mass of GaAs is 74%. In this case, an emission angle of the Ga_{X}In_{(1-X)}As photocathode film is 86% of an emission angle of the GaAs photocathode film. As a result, the brightness is 1.34 times higher. Even in this case, when the plane orientation of the surface of the photocathode film is the (110) plane, since the surface level is reduced and a higher current density can be obtained, higher brightness can be achieved.

### REFERENCE SIGN LIST

1 photocathode

2 condenser lens

3 extraction electrode

4 cathode holder

5 acceleration power source

6 window

7 parallel light source

8 optical spherical aberration correction unit

9 vacuum container

10 photocathode film

11 transparent substrate

12 excitation light

13 electron beam

14 opening

20 optical spherical aberration corrector

21 optical spherical aberration correction plate

22 photoexcited electron gun

23 electron optical system housing

24 electron lens

30 first convex lens

31 second convex lens

32 lens position adjusting mechanism

40 beam splitter

41 imaging element

42 collimator lens

43 light source

44 imaging lens

45 ND filter

46 reflected light

50 cathode pack

51 holder

52 transport mechanism

53 activation chamber

54 cathode stage

60 buffer layer

1. An electron beam application device comprising:
a photocathode including a substrate and a photocathode film;
a condenser lens configured to condense excitation light toward the photocathode;
an extraction electrode which is disposed facing the photocathode and configured to accelerate an electron beam generated from the photocathode film of the photocathode by condensing the excitation light with the condenser lens and emitting the excitation light that passes through the substrate of the photocathode on the photocathode film; and
an electron optical system in which the electron beam accelerated by the extraction electrode is guided, wherein
an optical spherical aberration correction plate having a refractive index equal to a refractive index of the substrate of the photocathode at a wavelength of the excitation light is disposed between the photocathode and the condenser lens.

2. The electron beam application device according to claim 1, wherein
a material of the optical spherical aberration correction plate is the same as a material of the substrate of the photocathode.

3. The electron beam application device according to claim 2, wherein
when a thickness at which a spherical aberration amount is minimized when the excitation light is focused on the material of the substrate of the photocathode with the condenser lens is L,
a sum of a thickness of the optical spherical aberration correction plate and a thickness of the substrate of the photocathode is equal to or less than L.

4. The electron beam application device according to claim 1, further comprising:
a cathode pack in which the optical spherical aberration correction plate and the photocathode are accommodated in a holder so that the optical spherical aberration correction plate and the substrate of the photocathode are in contact with each other; and
a cathode stage on which the cathode pack is placed.

5. The electron beam application device according to claim 4, further comprising:
a vacuum container in which the condenser lens, the extraction electrode, and the cathode stage are disposed; and
an activation chamber connected to the vacuum container for reactivating the photocathode film of the photocathode, wherein
the cathode pack is transported between the vacuum container and the activation chamber by a transport mechanism.

6. The electron beam application device according to claim 1, further comprising:
a parallel light source; and
an optical spherical aberration corrector configured to diverge or focus a parallel light emitted from the parallel light source, wherein
the parallel light that passes through the optical spherical aberration corrector is emitted to the condenser lens as the excitation light.

7. An electron beam application device comprising:
a parallel light source;
an optical spherical aberration corrector configured to diverge or focus a parallel light emitted from the parallel light source;
a photocathode including a substrate and a photocathode film;
a condenser lens configured to condense an excitation light toward the photocathode, the parallel light that passes through the optical spherical aberration corrector being configured to be emitted as the excitation light;
an extraction electrode which is disposed facing the photocathode and configured to accelerate an electron beam generated from the photocathode film of the photocathode by condensing the excitation light with the condenser lens and emitting the excitation light that passes through the substrate of the photocathode on the photocathode film; and
an electron optical system in which the electron beam accelerated by the extraction electrode is guided.

8. The electron beam application device according to claim 7, wherein
the optical spherical aberration corrector includes:
a first lens into which the parallel light is emitted;
a second lens into which the parallel light that passes through the first lens is emitted; and
a lens position adjusting mechanism configured to adjust a distance between the first lens and the second lens, and
at least one of the first lens and the second lens is a convex lens.

9. The electron beam application device according to claim 7, wherein
an optical spherical aberration correction plate having a refractive index equal to a refractive index of the substrate of the photocathode at a wavelength of the excitation light is disposed between the photocathode and the condenser lens.

10. The electron beam application device according to claim 1, wherein
in the photocathode, a material of the photocathode film is GaAs, and a plane orientation of a surface of the photocathode film is a (110) plane.

11. The electron beam application device according to claim 1, wherein
in the photocathode, a material of the photocathode film is a mixed crystal of GaAs and InAs, and an effective mass of a conduction band of the mixed crystal is smaller than an effective mass of a conduction band of GaAs.

12. The electron beam application device according to claim 11, wherein
a plane orientation of a surface of the photocathode film is a (110) plane.

13. The electron beam application device according to claim 7, wherein
in the photocathode, a material of the photocathode film is GaAs, and a plane orientation of a surface of the photocathode film is a (110) plane.

14. The electron beam application device according to claim 7, wherein
in the photocathode, a material of the photocathode film is GaAs, and a plane orientation of a surface of the photocathode film is a (110) plane.

15. The electron beam application device according to claim 14, wherein
a plane orientation of a surface of the photocathode film is a (110) plane.
